(19) United States
(12) Patent Application Publication
(10) Pub. No.: US 2010/0244109 A1
(43) Pub. Date: Sep. 30, 2010

(54) TRENCHED METAL-OXIDE-SEMICONDUCTOR DEVICE AND FABRICATION THEREOF

(75) Inventor: Hsiu Wen HSU, Xinfeng Shiang (TW)

Correspondence Address: Muncy, Geissler, Olds & Lowe, PLLC, 4000 Legato Road, Suite 310, FAIRFAX, VA, 22033, US

(73) Assignee: NIKO SEMICONDUCTOR CO., LTD., Taipei (TW)

(21) Appl. No.: 12/414,283

(22) Filed: Mar. 30, 2009

(51) Int. Cl. H01L 29/94; H01L 21/8234

(52) U.S. Cl. 257/296; 438/239; 257/E21.616; 257/E29.345

(57) ABSTRACT

A fabrication method of a trenched metal-oxide-semiconductor device is provided. After the formation of the gate dielectric layer, a first poly-silicon layer is deposited along the profile of the gate trench. Then, impurities of first conductivity type are implanted to the first poly-silicon layer at the bottom of the gate trench. Then, a second poly-silicon layer with second conductivity type is deposited over the first poly-silicon layer. The impurities in the first poly-silicon layer and the second poly-silicon layer are then driven by an annealing step to form a first doping region with first conductivity type located at the bottom of the gate trench and a second doping region with second conductivity type.

### BACKGROUND OF THE INVENTION

1. Field of the Invention

This invention relates to a trenched metal-oxide-semiconductor device and a fabrication method thereof, and more particularly relates to a trenched metal-oxide-semiconductor device with low gate to drain capacitance (Cgd) and a fabrication method thereof.

2. Description of Related Art

In the traditional planar metal-oxide-semiconductor devices, the current flows along the channel at the surface of the substrate. However, in the trench metal-oxide-semiconductor devices, the current flows along the channel perpendicular to the substrate by placing the gate electrodes in the trenches. Because trench metal-oxide-semiconductor devices provide a smaller cell pitch as compared to planar metal-oxide-semiconductor device, trench metal-oxide-semiconductor devices facilitate the reduction of die cost. Typical trench metal-oxide-semiconductor devices include MOSFET, IGBT, and etc.

Energy loss of metal-oxide-semiconductor devices can be sorted into conduction loss due to on-state resistance and switching loss due to gate charges (Qgd). Attending with the increasing of operating frequency, switching loss becomes more significant. Although it is well known that switching loss and switching speed can be promoted by reducing gate to drain capacitance (Cgd), however, complicated fabrication processes are usually unpreventable and the fabrication cost is thus increased.

Accordingly, it is an important topic in the art to find out a simple metal-oxide-semiconductor structure and a fabrication method thereof for reducing gate to drain capacitance.

### SUMMARY OF THE INVENTION

It is an object of the present invention to lower gate to drain capacitance of the metal-oxide-semiconductor device so as to reduce switching loss and enhance operating efficiency.

A fabrication method of a trench metal-oxide-semiconductor is provided. The fabrication method comprises the steps of: (a) providing a substrate; (b) forming an epitaxial layer on the substrate; (c) forming at least one gate trench in the epitaxial layer; (d) forming a gate dielectric layer on inner walls of the gate trench; depositing a first poly-silicon layer along surface profile of the inner walls of the gate trench; (e) implanting impurities of first conductivity type to the first poly-silicon layer adjacent to the bottom of the gate trench; (f) depositing a second poly-silicon layer with impurities of second conductivity type over the first poly-silicon layer; and (g) annealing the first poly-silicon layer and the second poly-silicon layer to drive in the impurities therein to form a first doping region of the first conductivity type and a second doping region of the second conductivity type, wherein the first doping region is located at the bottom of the gate trench and a PN junction capacitor is formed between the first doping region and the second doping region.

In an embodiment of the present invention, a metal silicide layer is formed on the second doping region for lowering gate resistance.

In an embodiment of the present invention, the first poly-silicon layer is covered with a sacrifice oxide layer before implanting impurities of the first conductivity type so as to prevent the impurities from being implanted to the first poly-silicon layer at the sidewalls of the gate trench.

In an embodiment of the present invention, the impurities of the first conductivity type is implanted to the exposed first poly-silicon layer along an implanting direction perpendicular to the substrate.

According to the above mentioned fabrication method, a trench metal-oxide-semiconductor device is also provided in the present invention. The trench metal-oxide-semiconductor device comprises a substrate, an epitaxial layer, at least one gate trench, a gate dielectric layer, and a poly-silicon gate. The epitaxial layer is formed on the substrate. The gate trench is located in the epitaxial layer. The gate dielectric layer is formed over the inner walls of the gate trench. The poly-silicon gate is located in the gate trench. The poly-silicon gate has a first doping region of first conductivity type and a second doping region of second conductivity type, wherein the first doping region is located at the bottom of the gate trench, the second doping region is located on the first doping region, and an PN junction capacitor is formed between the first doping region and the second doping region.

In contrast with traditional trench metal-oxide-semiconductor device, the trench metal-oxide-semiconductor device provided in the embodiment of the present invention features a poly-silicon gate with the first doping region of the first conductivity type and the second doping region of the second conductivity type. Therefore, the overall gate to drain capacitance comes from the capacitor composed of the epitaxial layer, the gate dielectric layer, and the first doping region as well as the PN junction capacitor between the first doping region and the second doping region. Since the two capacitors are connected in a serial, the existence of the junction capacitor is helpful for lowering gate to drain capacitance so as to reduce switching loss and enhance operating efficiency.

### BRIEF DESCRIPTION OF THE DRAWINGS

The present invention will now be specified with reference to its preferred embodiment illustrated in the drawings, in which:

FIGS. 1A to 1E are schematic views showing a first embodiment of the fabrication method of the trench metal-oxide-semiconductor device in accordance with the present invention;

FIG. 2 is a schematic view showing a second embodiment of the fabrication method of the trench metal-oxide-semiconductor device in accordance with the present invention; and

FIG. 3 is a schematic view showing a third embodiment of the fabrication method of the trench metal-oxide-semiconductor device in accordance with the present invention.

### DESCRIPTION OF THE PREFERRED EMBODIMENT

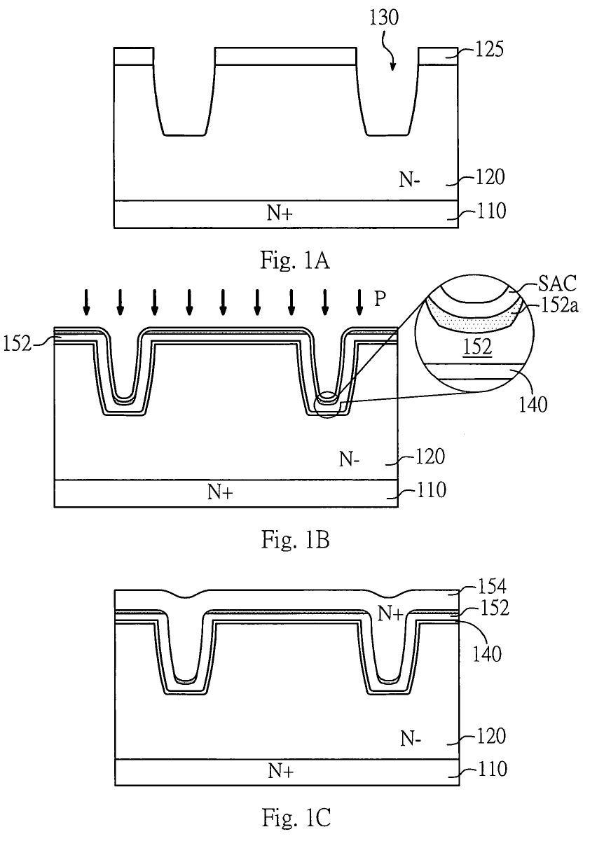

FIGS. 1A to 1E are schematic views showing the first embodiment of the fabrication method of a trench metal-oxide-semiconductor in accordance with the present invention. As shown in FIG. 1A, a substrate 110 is provided, and an epitaxial layer 120 is formed on the substrate 110. Afterward, a photo-resist pattern 125 is formed on the upper surface of the epitaxial layer 120 to define the location of at least one gate trench 130. Then, the epitaxial layer 130 is etched through the photo-resist layer 125 to form the gate trench 130 in the epitaxial layer 120.

Afterward, referring to FIG. 1B, after removing the photo-resist layer 125, a gate dielectric layer 140 is formed on the inner walls of the gate trench 130. For example, the gate dielectric layer 140 may be composed of silicon oxide or silicon nitride. As to the aspect of fabrication, the gate dielectric layer 140 composed of silicon oxide can be formed on the exposed surfaces of the epitaxial layer 120 by thermal oxidation treatment. In addition, the gate dielectric layer 140 composed of silicon oxide or silicon nitride can be formed on the epitaxial layer 120 by using a chemical vapor deposition process.

Afterward, a first poly-silicon layer 152 is deposited over the gate dielectric layer 140 along surface profile of the upper surface of the epitaxial layer 120 as well as the inner walls of the gate trench 130. The first poly-silicon layer may be an un-doped poly-silicon layer or a lightly-doped poly-silicon layer. The lightly doped one can be P-type doped or N-type doped. In practice, as a preferred embodiment, doping concentration of the first poly-silicon layer 152 should be smaller than 5e17 #/cm³.

Thereafter, a sacrifice oxide layer SAC is formed over the first poly-silicon layer 152. An ion implantation step is then carried out to implant P-type impurities (such as Boron) through the sacrifice oxide layer SAC to the first poly-silicon layer 152 with the implanting direction substantially perpendicular to the substrate 110. The implanted region is labeled as 152a in the figure. It is noted that, the implanting direction of P-type impurities is also perpendicular to the bottom of the gate trench 130 but with a great incident angle with respect to the sidewalls of the gate trench 130. Therefore, it is much more difficult for the P-type impurities to penetrate the sacrifice oxide layer SAC to reach the first poly-silicon layer 152 on the sidewalls of the gate trench 130. Accordingly, with properly controlled implanting energy, the P-type impurities can be selectively implanted to the first poly-silicon layer 152 adjacent to the bottom of the gate trench 130.

Afterward, referring to FIG. 1C, after removing the sacrifice oxide layer SAC, a second poly-silicon layer 154 is deposited over all the exposed surfaces to cover the first poly-silicon layer 152 and fill the gate trench 130. The second poly-silicon layer 154 is directly connected to the first poly-silicon layer 152 and is doped with N-type impurities. The concentration of N-type impurities in the second poly-silicon layer 154 is greater than that of the original first poly-silicon layer 152. Thereafter, referring to FIG. 1D, an etching back step is carried out to remove unwanted portions of the first poly-silicon layer 152 and the second poly-silicon layer 154 to leave the poly-silicon gate 150 in the gate trench 130. As shown, the poly-silicon gate 150 includes the first poly-silicon layer 152 adjacent to the gate dielectric layer 140 and the second poly-silicon layer 154 at the center of the poly-silicon gate.

Afterward, referring to FIG. 1E, the first poly-silicon layer 152 and the second poly-silicon layer 154 are annealed to diffuse the impurities therein. The high concentration P-type impurities implanted to the first poly-silicon layer 152 adjacent to the bottom of the gate trench 130 as shown in FIG. 1D are diffused to form a P-type first doping region 158 at the bottom of the gate trench 130. Whereas, because the concentration of P-type impurities in the first poly-silicon layer 152 on the sidewalls of the gate trench 130 is much smaller than the concentration of N-type impurities in the adjacent second poly-silicon layer 154, conductivity type of the first poly-silicon layer 152 on the sidewalls of the gate trench 130 would be changed by the N-type impurities from the second poly-silicon layer 154, so that a second doping region 156 composed of the second poly-silicon layer 154 and a portion of the first poly-silicon layer 152 on the sidewalls of the gate trench 130 is formed. As shown in FIG. 1E, the resulted N-type second doping region 156 is located on the P-type first doping region 158 and a PN junction surface is formed between the two doping regions 156,158. As the trench metal-oxide-semiconductor device is operating, a junction capacitor is formed at the PN junction surface to lower gate to drain capacitance.

As shown in FIG. 1E, after the poly-silicon gate 150 is formed in the gate trench 130, it is a typical step to implant P-type impurities to the epitaxial layer 120 and anneal the epitaxial layer 120 to diffuse the implanted P-type impurities to form the body 122 of the trench metal-oxide-semiconductor device. In the present embodiment, the above mentioned annealing process is used to diffuse the P-type and N-type impurities in the poly-silicon gate 150 to form the P-type first doping region 158 and the N-type doping region 156. Therefore, the present embodiment does not need additional annealing step solely for forming the first doping region 158 and the second doping region 156.

Afterward, N-type impurities are implanted to the body 122 to form source regions 160. Then, a dielectric layer 170 is formed over the gate trench 130 to cover the poly-silicon gate 150. Thereafter, the dielectric layer 170 is utilized as a mask for implanting P-type impurities to the body 122 to form P-type heavily-doped region 180 between two neighboring source regions 160 to finish the fabrication method.

As mentioned above, in the present embodiment, the body 122 is formed after the formation of the poly-silicon gate 150. However, the scope of the present invention is not so limited. It is well known that body of the metal-oxide-semiconductor device can be formed before the formation of gate trench 130 by depositing a body layer over the epitaxial layer 120 so as to skip the step of body implantation. The present invention is also applicable to this typical fabrication process. In detail, although the step of body implantation is saved, the step of source implantation is still remained. The annealing step for forming the source regions 160 can be used to diffuse the impurities in the poly-silicon gate 150 to form the first doping region 158 and the second doping region 156.

In the present embodiment, the portion of the first poly-silicon layer 152 adjacent to the bottom of the gate trench 130 is implanted with P-type impurities and the second poly-silicon layer 154 is doped with N-type impurities. However, the present invention is not limited to the specific embodiment. To form a junction capacitor between the first doping region 158 and the second doping region 156, the first poly-silicon layer 152 may be implanted with N-type impurities and the second poly-silicon layer 154 may be formed by using poly-silicon material with P-type impurities. Moreover, doping concentration of the first doping region 158 and the second doping region 156 should be high enough to control gate resistance. For example, doping concentration of the first doping region 158 or the second doping region 156 is usually greater than the doping concentration of the body 122. In practice, doping concentration of body 122 of the metal-oxide-semiconductor device is substantially ranged between 1e16 #/cm³˜1e18 #/cm³, and doping concentration of P-type impurities in the first doping region 158 or N-type impurities in the second doping region 156 should be ranged between 1e18 #/cm³˜1e20 #/cm³.

In the present embodiment, the first poly-silicon layer 152 may be an un-doped poly-silicon layer or a lightly-doped one with the doping concentration smaller than 5e17 #/cm³. However, the scope of the present invention is not so limited. The doping concentration of the first poly-silicon layer 152 depends on the amount of P-type impurities implanted to the first poly-silicon layer 152. As long as the amount of P-type impurities implanted to the first poly-silicon layer 152 being able to overcome the N-type impurities in the original first poly-silicon layer 152 to form P-type first doping region 158, it is adoptable to the present invention.

FIG. 1E also shows an embodiment of the trench metal-oxide-semiconductor device in accordance with the present invention. As shown, the trench metal-oxide-semiconductor device 100 has a substrate 110, an epitaxial layer 120, at least one gate trench 130, a P-body 122, a gate dielectric layer 140, a poly-silicon gate 150, at least a source region 160, and a dielectric layer 170. The epitaxial layer 120 is located on the substrate 110. The gate trench 130 is located in the epitaxial layer 120 and is extended from an upper surface of the epitaxial layer 120 into the epitaxial layer 120.

The P-body 122 is located in the epitaxial layer 120 and surrounds the gate trench 130. The gate dielectric layer 140 lines the inner walls of the gate trench 130. The poly-silicon gate 150 is located in the gate trench 130. The source regions 160 are located in the P-body 122 and adjacent to the gate trench 130. In addition, a P-type heavily-doped region 180 is located in the P-body 122 between two neighboring source regions 160.

The poly-silicon gate 150 has a P-type first doping region 158 and an N-type second doping region 156. The first doping region 158 is located at the bottom of the gate trench 139, the second doping region 156 is located on the first doping region 158, and a PN junction surface is formed between the first doping region 158 and the second doping region 156. As a preferred embodiment, the bottom surface of the gate trench 130 is totally covered by the first doping region 158.

Also referring to FIG. 1D, the poly-silicon gate 150 can be understood as being composed of the first poly-silicon layer 152, which is adjacent to the gate dielectric layer 140 on the sidewalls and bottom surface of the gate trench 130, and the second poly-silicon layer 154, which is located at the center of the gate trench 130. The above mentioned first doping region 158 is substantially totally located in the first poly-silicon layer 152.

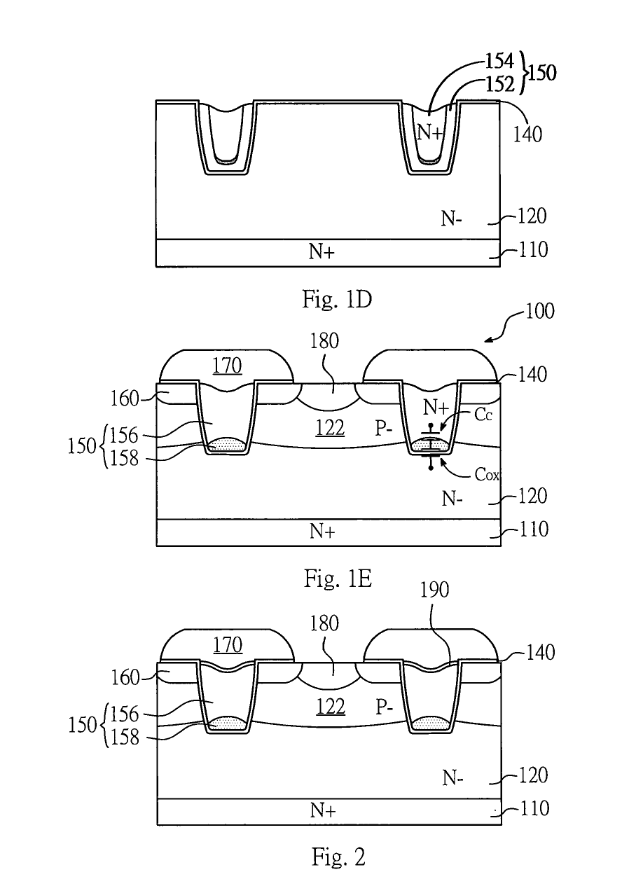

FIG. 2 is a schematic view showing a second embodiment of the fabrication method of the trench metal-oxide-semiconductor device in accordance with the present invention. The difference between the present embodiment and the first embodiment is described below. In the present embodiment, a metal silicide layer 190 for reducing gate resistance is formed on the upper surface of the second doping region 156 after the formation of the poly-silicon gate 150. The metal silicide layer 190 can be formed by using typical self-aligned silicide (salicide) fabrication process. The typical salicide fabrication process needs an annealing step to form metal silicide (such as titanium silicide). This annealing step can be used to diffuse the impurities in the poly-silicon gate 150 to form the first doping region 158 and the second doping region 156.

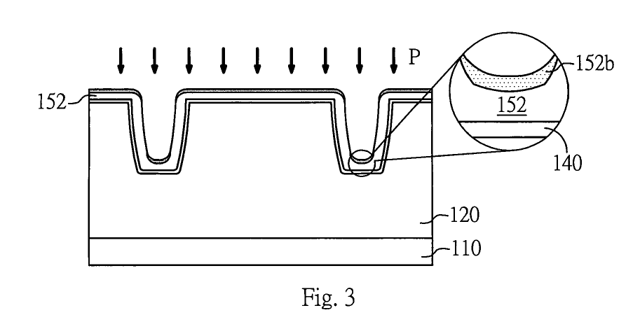

FIG. 3 is a schematic view showing a third embodiment of the fabrication method of the trench metal-oxide-semiconductor device in accordance with the present invention. The difference between the present embodiment and the first embodiment is described below. In contrast with the first embodiment, which forms the sacrifice oxide layer SAC over the first poly-silicon layer 152 for selectively implanting P-type impurities to the first poly-silicon layer 152 at the bottom of the gate trench 130, the present embodiment skips the step of forming the sacrifice oxide layer SAC and implanting P-type impurities to the exposed first poly-silicon layer 152 directly. In detail, because the exposed surface of the first poly-silicon layer 152 on the sidewalls of the gate trench 130 is substantially parallel to the implanting direction of the P-type impurities, seldom of the P-type impurities can be implanted to the first poly-silicon layer 152 on the sidewalls of the gate trench 130 even the sacrifice oxide layer SAC is skipped. Therefore, the object of selectively implanting P-type impurities to the first poly-silicon layer 152 at the bottom of the gate trench 130 can be achieved. The implanted region is labeled as 152b in this figure. In addition, because the step of forming sacrifice oxide layer SAC is skipped in the present embodiment, referring to FIG. 1C, after implanting P-type impurities to the first poly-silicon layer 152, the second poly-silicon layer 152 can be deposited on the first poly-silicon layer 154 directly without the need of removing the sacrifice oxide layer SAC first.

Referring to FIG. 1E, gate to drain capacitance (Cgd) of the trench metal-oxide-semiconductor device in accordance with the present invention comes from the capacitor Cox, which is composed of the epitaxial layer 120, the gate dielectric layer 140, and the first doping region 158, and the serially connected junction capacitor Cc, which is located between the first doping region 158 and the second doping region 156. The existence of the junction capacitor Cc is capable to have gate to drain capacitance smaller than that of the capacitor Cox crossing the gate dielectric layer 140. Thus, the junction capacitor Cc is helpful for lowering gate to drain capacitance so as to reduce switching loss and enhance operating efficiency.

While the preferred embodiments of the present invention have been set forth for the purpose of disclosure, modifications of the disclosed embodiments of the present invention as well as other embodiments thereof may occur to those skilled in the art. Accordingly, the appended claims are intended to cover all embodiments which do not depart from the spirit and scope of the present invention.

What is claimed is:

1. A fabrication method of a trench metal-oxide-semiconductor comprising:
providing a substrate;
forming an epitaxial layer on the substrate;
forming at least one gate trench in the epitaxial layer;
forming a gate dielectric layer on inner walls of the gate trench;
depositing a first poly-silicon layer along surface profile of the inner walls of the gate trench;
implanting impurities of first conductivity type to the first poly-silicon layer adjacent to the bottom of the gate trench;
depositing a second poly-silicon layer with impurities of second conductivity type over the first poly-silicon layer; and
annealing the first poly-silicon layer and the second poly-silicon layer to diffuse the impurities therein to form a first doping region of the first conductivity type and a second doping region of the second conductivity type, wherein the first doping region is located at the bottom of the gate trench and an PN junction capacitor is formed between the first doping region and the second doping region.

2. The fabrication method of claim 1, further comprising the step of forming a sacrifice oxide layer covering the first poly-silicon layer, wherein the impurities of the first conductivity type are implanted to the first poly-silicon layer through the sacrifice oxide layer and the sacrifice oxide layer is removed before depositing the second poly-silicon layer over the first poly-silicon layer.

3. The fabrication method of claim 1, wherein the first poly-silicon layer is an un-doped poly-silicon layer or a lightly-doped poly-silicon layer.

4. The fabrication method of claim 1 further comprising the step of forming a metal silicide layer on the second doping region.

5. The fabrication method of claim 1, after the second poly-silicon layer is deposited over the first poly-silicon layer, further comprising the step of etching back the first poly-silicon layer and the second poly-silicon layer to form a poly-silicon gate in the gate trench.

6. The fabrication method of claim 1, wherein concentration of the impurities of the first conductivity type in the first doping region is greater than that of body of the trench metal-oxide-semiconductor device.

7. The fabrication method of claim 1, wherein concentration of the impurities of the first conductivity type in the first doping region is close to than that of impurities of the second conductivity type in the second doping region.

8. The fabrication method of claim 1, wherein the impurities of the first conductivity type is implanted along an implanting direction substantially perpendicular to the substrate.

9. A trench metal-oxide-semiconductor device comprising:
a substrate;
an epitaxial layer, formed on the substrate;
at least one gate trench, located in the epitaxial layer;
a gate dielectric layer, located on inner walls of the gate trench; and
a poly-silicon gate, having a first doping region of first conductivity type and a second doping region of second conductivity type, wherein the first doping region is located at the bottom of the gate trench, the second doping region is located on the first doping region, and an PN junction capacitor is formed between the first doping region and the second doping region.

10. The trench metal-oxide-semiconductor device of claim 9, wherein the first poly-silicon layer is an un-doped poly-silicon layer or a lightly-doped poly-silicon layer.

11. The trench metal-oxide-semiconductor device of claim 9, further comprising a metal silicide layer, formed on the second doping region.

12. The trench metal-oxide-semiconductor device of claim 9 further comprising a body, located in the epitaxial layer and surrounding the gate trench, wherein concentration of the impurities of the first conductivity type in the first doping region is greater than that in the body.

13. The trench metal-oxide-semiconductor device of claim 9, wherein concentration of the impurities of the first conductivity type in the first doping region is close to than that of impurities of the second conductivity type in the second doping region.

14. The trench metal-oxide-semiconductor device of claim 9, wherein the poly-silicon gate includes a first poly-silicon layer and a second poly-silicon layer, the first poly-silicon layer is adjacent to the gate dielectric layer, the second poly-silicon layer is located at center of the poly-silicon gate, and the first doping region is substantially located in the first poly-silicon layer.
